(19) United States
(12) Patent Application Publication
(10) Pub. No.: US 2016/0109524 A1
(43) Pub. Date: Apr. 21, 2016

(54) Arrangement for Determining Characteristic Variables of an Electrochemical Energy Store

(71) Applicants: ROBERT BOSCH GMBH, Stuttgart (DE); SAMSUNG SDI CO., LTD., Yongin-si, Gyeonggi-do (KR)

(72) Inventor: Stefan Butzmann, Schalksmühle (DE)

(21) Appl. No.: 14/895,465

(22) PCT Filed: Apr. 11, 2014
(86) PCT No.: PCT/EP2014/057403

§ 371 Date: Dec. 2, 2015

(30) Foreign Application Priority Data
Jun. 4, 2013 (DE) 10 2013 210 298.4

(51) Int. Cl. G01R 31/36; H01M 2/34; H01M 10/48; G01R 15/20

(52) U.S. Cl. CPC G01R 31/3644; G01R 15/205; H01M 2/348; H01M 10/48

(57) ABSTRACT

An arrangement for determining characteristic variables of an electrochemical energy store comprises a gradient sensor with a bridge circuit including anisotropic magnetoresistive resistance elements. The arrangement additionally comprises a conductor through which a current from the energy store flows during operation of the energy store. The conductor includes a first section configured to primarily magnetically influence a first side of the bridge circuit and a second section configured to primarily magnetically influence a second side of the bridge circuit. The first section and the second section are arranged with respect to the bridge circuit in such a manner that a flow of current through the conductor produces a measurable electrical voltage across the bridge circuit.

### BACKGROUND INFORMATION

The present invention relates to an arrangement for determining parameters of an electrochemical energy store. In particular, the present invention relates to an option for increasing the robustness and the economical integration of a measuring functionality into terminals of an electrochemical energy store.

Current sensors are typically integrated into batteries for determining various battery parameters, for example, the state of charge, a charging current, etc. Up to now, these current sensors have been designed as shunt sensors or Hall sensors. Although these known systems are comparatively economical, their immunity to malfunction is not sufficient for every application. In addition, it is not possible to integrate them into the electrochemical energy stores in a sufficiently simple and economical manner. For example, a shunt must be integrated into the current flow of the electrochemical energy store in order to be able to tap and evaluate a voltage which is proportional to the current flow via the shunt. Hall sensors may be easily influenced by external magnetic fields and therefore do not constitute a sufficiently accurate measuring arrangement under certain circumstances. The object of the present invention is therefore to dispel the known disadvantages in the related art in measuring electrical parameters of an electrochemical energy store.

### SUMMARY OF THE INVENTION

According to the present invention, a system for determining parameters of an electrochemical energy store is provided. This system achieves the aforementioned object with the aid of the following integral parts. A first integral part of the arrangement is a gradient sensor comprising a bridge circuit made up of anisotropic magnetoresistive resistor elements. The structure of a bridge circuit may be described by a parallel connection of two series connections of two electrical components, wherein a bridge voltage between the components connected in series may be determined. This voltage is in particular a function of the sizing of the electrical components of the bridge circuit. According to the present invention, anisotropic magnetoresistive resistor elements are used. Their resistance is a function of a direction and magnitude of a magnetic field acting on them or in them. Reference is made to the relevant technical literature concerning the anisotropic magnetoresistive effect. In addition, the arrangement comprises a conductor through which current of the energy store flows during the operation of the energy store. The current is such that it makes it possible for information about the parameters to be determined. The conductor may, for example, be situated at a terminal contact of the electrochemical energy store or at one of its cells. This conductor has a first section which is configured primarily to influence a first side of the bridge circuit magnetically. In particular, a spatial proximity, for example, parallel to a first and a third element of the bridge circuit, is suitable for this purpose.

To improve the linearity, the preferred direction of the first electrical component or its AMR material may be arranged differently than the preferred direction of the third electrical component or its AMR material. In particular, the preferred directions of both AMR materials connected in series may preferably be arranged perpendicularly (90°) to each other. In this way, it is possible in a simple manner to achieve an essentially linear dependence of the change in resistance on the magnetic field acting on the elements. Similarly, a second section of the conductor is configured primarily to influence a second side of the bridge circuit magnetically. The designs made in connection with the first section apply. According to the present invention, the first section and the second section are arranged with respect to the bridge circuit in such a way that a current flow through the conductor generates a voltage which is measurable across the bridge circuit. For this purpose, a supply voltage induces a current in the bridge circuit which generates voltage drops and thus a bridge voltage in the elements of the bridge circuit as a function of the current flow or its magnetic field. For example, the first branch of the bridge circuit and the second branch of the bridge circuit may be configured symmetrically with respect to each other. In this way, a current flow directed through the first section of the conductor and the second section of the conductor in opposite directions generates opposite voltage changes in the first branch and in the second branch. This may be differentially measured as a bridge voltage or bridge signal. This provides the advantage that the arrangement according to the present invention is essentially robust with respect to the effect of external magnetic fields. The device according to the present invention is thus suitable in particular for use in transportation means and automobiles.

The subclaims describe preferred refinements of the present invention.

Preferably, the conductor is designed as a fuse, in particular as a melting fuse, which is frequently provided in any case for protecting an electrochemical energy store. The fuse is usually situated in an easily accessible area of the energy store in order to be able to replace the fuse easily and economically after it blows. This provides the advantage that the integration of the arrangement according to the present invention is also economical, since it is able to be carried out in an easily accessible area.

Preferably, the first section of the conductor is essentially parallel to the first side of the bridge circuit. In addition, the second section of the conductor is oriented essentially parallel to or antiparallel to the second side of the bridge circuit. In this way, an effect of the first section is ensured in particular on the first side of the bridge circuit, and an effect of the second section is ensured in particular on the second side of the bridge circuit. In the case of an antiparallel arrangement, although the conductors are arranged parallel to each other or parallel to a particular branch of the bridge circuit, the current flows through them in opposite directions. In this way, a reliable response or a high sensitivity of the bridge circuit is ensured, and the robustness with respect to external magnetic fields may be further increased.

Furthermore, the first section and the second section of the conductor are preferably arranged in series with each other. In other words, the same current first flows through the first section of the conductor, and subsequently flows through the second section. For this purpose, the conductor may be routed around the bridge circuit in a loop shape. This arrangement provides the advantage that the current conduction through the conductor is simple to establish despite adaptation to the bridge circuit.

In particular, the conductor is preferably U-shaped, wherein the parallel legs of the “U” are formed by the first section and the second section of the conductor. These parallel legs are essentially responsible for the measurable effect of the current on the bridge circuit, while the bottom or trough of the “U” essentially has no influence on the measuring arrangement.

Preferably, the first section and the second section of the conductor are situated in a plane other than that of the resistor elements of the bridge circuit. If it is assumed, for example, that each of the elements of the bridge circuit are distributed in their shared plane to a greater degree than in a direction perpendicular to the shared plane, such magnetic field components in particular have an influence on the resistance of the AMR material of the elements which extend in the same shared direction. Since the magnetic field of an (infinitely long) conductor encloses the conductor in concentric circles, a particularly strong effect may be generated on the bridge voltage in different planes via the preferred arrangement. The effect on the bridge voltage is particularly strong if the first section and the second section of the conductor are arranged offset in a direction perpendicular to the main plane of the bridge elements. This provides the advantage that the bridge circuit is particularly sensitive with respect to the current flowing through the electrochemical energy store.

The conductor may preferably be fabricated as a stamped part, in particular from sheet copper. This is already the case today in many applications. By merely making minor tool changes, the conductor may be designed in such a way that a simple positioning with respect to the gradient sensor according to the present invention is made possible.

Preferably, the gradient sensor is designed as a prefabricated assembly. In other words, the bridge circuit, optionally also evaluation electronics of the gradient sensor, may be integrated into a separate component which is subsequently fixed at the conductor of the electrochemical energy store. This may in particular be carried out with the aid of an adhesive connection. Alternatively, the gradient sensor may also be connected to the conductor of the electrochemical energy store, in particular also to the housing of the electrochemical energy store, by means of a resin or via a mold process. This also makes the arrangement according to the present invention robust with respect to mechanical influences. In addition, a fluid-impermeable connection may be established for preventing corrosion.

According to another aspect of the present invention, an electrochemical store is placed under protection which comprises at least one arrangement according to the present invention as discussed above in detail. In particular, the electrochemical store may comprise multiple electrochemical storage cells which comprise an arrangement according to the present invention in each case or which may be protected via a shared arrangement according to the present invention.

### BRIEF DESCRIPTION OF THE DRAWINGS

Exemplary embodiments of the present invention are described in detail below with reference to the accompanying drawings. In the drawings:

FIG. 1 shows a measuring arrangement by means of a shunt;

FIG. 2 shows a schematic view of a bridge circuit including anisotropic magnetoresistive resistor elements;

FIG. 3 shows a schematic representation of an electrochemical storage cell including a melting fuse; and

FIG. 4 shows a schematic arrangement of a gradient sensor according to the present invention in combination with an electrical conductor of an electrochemical store.

### DETAILED DESCRIPTION OF THE INVENTION

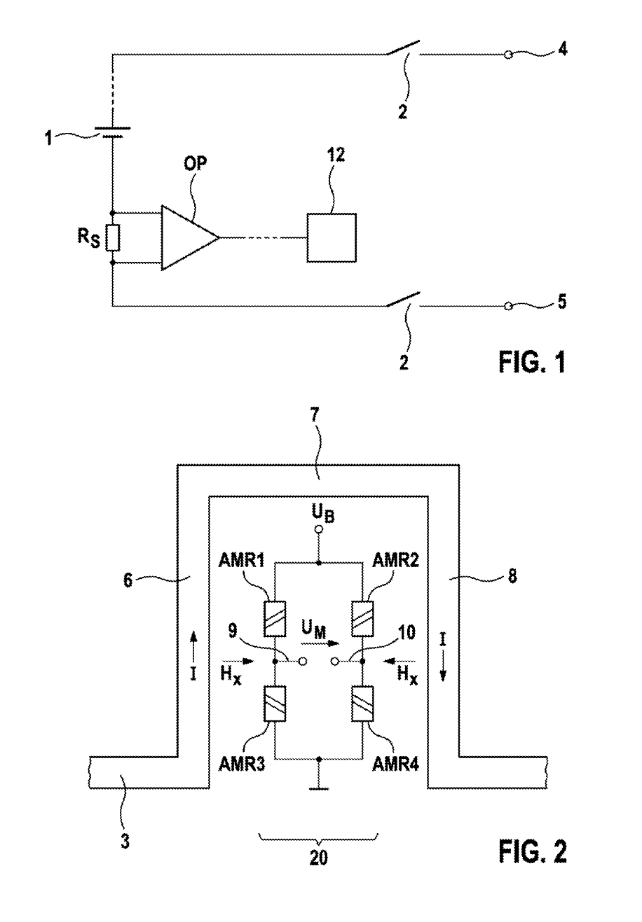

FIG. 1 shows an arrangement for measuring a current and protecting an electrochemical energy store. A cell 1 of the electrochemical energy store is depicted by way of example, in series with which a shunt R_{S} is arranged. The input of an operational amplifier OP is arranged across the shunt R_{S}, acting as a measuring amplifier whose output is connected to a microcontroller 12 acting as an evaluating unit. Two fuses 2 are provided between the elements described above and each electrical terminal 4, 5 of the electrochemical store.

FIG. 2 shows an electrical conductor 3 which is essentially gate-shaped or horseshoe-shaped. A first section 6 and a second section 8 are arranged essentially parallel to each other. The same current I flows through them, which is conducted through a third section 7 between the first section 6 and the second section 8. A gradient sensor including a bridge circuit 20 is arranged essentially parallel to the sections 6, 8, offset perpendicularly to the plane of the drawing. The bridge circuit has a first side comprising a first anisotropic magnetoresistive resistor element AMR1 and an anisotropic magnetoresistive resistor element AMR3 which is arranged in series with it. Parallel to this branch, a second side of the bridge circuit 20 is provided which includes a third anisotropic magnetoresistive resistor element AMR2 and a fourth anisotropic magnetoresistive resistor element AMR4. A bridge voltage U_{M} is generated between the resistor elements of the first and the second sides, in that the current flow I induces magnetic field components H_{X} pointed in different directions. Preferred directions, which are oriented perpendicular to each other within the two sides of the bridge circuit 20, of the resistor elements connected in series, are indicated by parallel lines in the resistor elements AMR1 to AMR4. However, since both sides of the bridge circuit 20 are structured symmetrically, the components H_{X} of the sections 6, 8 arranged parallel to the sides of the bridge circuit, which are oriented in opposite directions, result in voltage changes having opposite signs. Due to a supply voltage U_{B} across the bridge circuit 20, the measuring taps 9 and 10 on both sides of the bridge circuit 20 are at different electric potentials. The advantage of this arrangement is now that in the case of irradiation of a static magnetic field (for example, via an external disturbance), both half bridges are equally affected. In other words, an external disturbing field does not enter into the measurement result (the bridge voltage U_{M}).

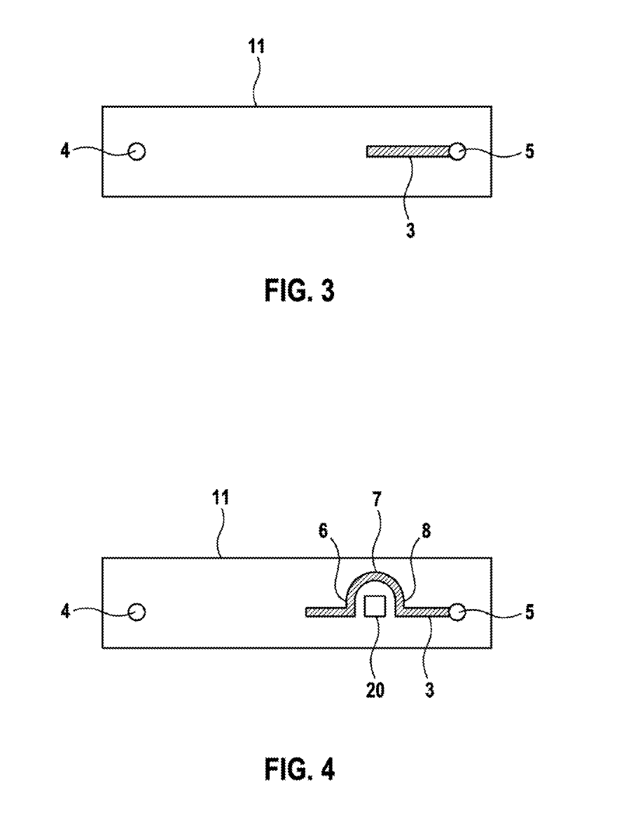

FIG. 3 shows a storage cell 11 of an electrochemical energy store which includes two externally contactable terminals 4, 5. One of the electrical terminals 5 includes a cell fuse which is implemented via a metal bar 3. A current flows through the metal bar 3 which also flows through the cell 11. In the case of an overheating of the metal bar 3 (for example, due to an excessive current flow through the cell 11), the metal bar 3 melts, thus constituting a melting fuse for the cell 11.

FIG. 4 shows an embodiment according to the present invention of an arrangement of a bridge circuit 20 of a gradient sensor at a metal bar 3 acting as a conductor of the cell 11. The conductor 3 is essentially U-shaped, wherein a first section 6 and a second section 8 of the conductor 3 may be routed past the bridge circuit 20 on opposite sides. The first section 6 and the second section 8 are connected to each other via a third section 7 of the conductor 3. The bridge circuit 20 is depicted inside the U. As already indicated above, it may be advantageous that the gradient sensor or the bridge circuit 20 is arranged offset in a direction perpendicular to the plane of the drawing or perpendicular to the direction of extension of the U, for example, above the conductor. With information about the current ascertained according to the present invention, all essential parameters, such as the charging and aging state, may thus be determined for each individual cell with an electronic system implemented on the cell 11 which also measures the cell voltage.

Even if the aspects according to the present invention and advantageous specific embodiments have been described in detail based on the exemplary embodiments explained in connection with the attached drawing figures, modifications and combinations of features are possible for those skilled in the art without departing from the scope of the present invention, the scope of protection thereof being defined via the attached claims.

1. An arrangement for determining parameters of an electrochemical energy store, comprising:
a gradient sensor comprising a bridge circuit including anisotropic magnetoresistive resistor elements; and
a conductor through which current of the energy store flows during operation of the energy store, the conductor including
first section configured primarily to influence a first side of the bridge circuit magnetically, and
a second section configured primarily to influence a second side of the bridge circuit magnetically,
wherein the first section and the second section are arranged with respect to the bridge circuit in such a way that a current flow through the conductor generates a voltage which is measurable across the bridge circuit.

2. The arrangement as claimed in claim 1, wherein the conductor is configured as a fuse.

3. The arrangement as claimed in claim 1, wherein the first section is oriented essentially parallel to the first side and the second section is oriented essentially parallel or antiparallel to the second side.

4. The arrangement as claimed in claim 1, wherein the first section and the second section are arranged in series with each other.

5. The arrangement as claimed in claim 1, wherein the conductor is U-shaped and parallel legs of the “U” are formed by the first section and the second section of the conductor.

6. The arrangement as claimed in claim 1, wherein the first section and the second section of the conductor are located in a plane other than that of the resistor elements of the bridge circuit of the gradient sensor.

7. The arrangement as claimed in claim 1, wherein the conductor is fabricated as a stamped part.

8. The arrangement as claimed in claim 1, wherein the gradient sensor is configured as a prefabricated assembly and/or is fixed relative to the conductor by an adhesive connection.

9. The arrangement as claimed in claim 1, wherein the conductor is located at least on one side at a terminal connector of the electrochemical energy store.

10. An electrochemical store comprising:
an arrangement configured to determine parameters of an electrochemical energy store, including
a gradient sensor comprising a bridge circuit including anisotropic magnetoresistive resistor elements, and
a conductor through which current of the energy store flows during operation of the energy store, the conductor including a first section configured primarily to influence a first side of the bridge circuit magnetically, and a second section configured primarily to influence a second side of the bridge circuit magnetically,
wherein the first section and the second section are arranged with respect to the bridge circuit in such a way that a current flow through the conductor generates a voltage which is measurable across the bridge circuit.

11. The arrangement as claimed in claim 2, wherein the fuse is a melting fuse.

12. The arrangement as claimed in claim 7, wherein the conductor is fabricated from copper.
